(19) United States
(12) Patent Application Publication
(10) Pub. No.: US 2024/0153889 A1
(43) Pub. Date: May 9, 2024

(54) INTEGRATED CIRCUIT INCLUDING GUARD-RING AND METHOD OF DESIGNING THE SAME

(71) Applicant: Samsung Electronics Co., Ltd., Suwon-si (KR)

(72) Inventors: Hankyung Kim, Suwon-si (KR); Seungkwon Lee, Suwon-si (KR)

(21) Appl. No.: 18/386,281

(22) Filed: Nov. 2, 2023

(30) Foreign Application Priority Data
Nov. 8, 2022 (KR) 10-2022-0148198
Mar. 14, 2023 (KR) 10-2023-0033464

(51) Int. Cl. H01L 23/58; H01L 21/768; H01L 23/48; H01L 23/528

(52) U.S. Cl. CPC H01L 23/585; H01L 21/76898; H01L 23/481; H01L 23/528

(57) ABSTRACT

Provided is an integrated circuit including a plurality of blocks, wherein each of the plurality of blocks includes devices formed in an device layer between a front-side wiring layer and a backside wiring layer, and a block guard-ring surrounding the devices, wherein the block guard-ring includes a first through silicon via extending from a first backside pattern of the backside wiring layer toward the front-side wiring layer, wherein the first backside pattern is configured to apply a first supply voltage or a second supply voltage provided to at least one of the devices.

### CROSS-REFERENCE TO RELATED APPLICATIONS

This application is based on and claims priority under 35 U.S.C. § 119 to Korean Patent Application Nos. 10-2022-0148198, filed on Nov. 8, 2022, and 10-2023-0033464, filed on Mar. 14, 2023, in the Korean Intellectual Property Office, the disclosures of both of which are incorporated by reference herein in their entireties.

### BACKGROUND

The technical idea of the inventive concept relates to an integrated circuit, and more particularly, to an integrated circuit including a guard-ring and a method of designing the same.

Due to the development of semiconductor processes, integrated circuits may have a high degree of integration, and various blocks may be included in one integrated circuit. For example, one chip separated from a wafer may include a block for processing a digital signal as well as a block for processing an analog signal. In addition, active devices, such as transistors and diodes as well as passive devices, such as resistors and capacitors may be included in one chip. For requirements of a semiconductor process and/or to prevent interference between blocks, an integrated circuit may include a guard-ring surrounding blocks.

### SUMMARY

The inventive concept provides an integrated circuit including a guard-ring providing a power transmission path and a method of designing the same.

According to an aspect of the inventive concept, there is provided an integrated circuit including a plurality of blocks, wherein each of the plurality of blocks includes devices formed in an device layer between a front-side wiring layer and a backside wiring layer, and a block guard-ring surrounding the devices, wherein the block guard-ring includes a first through silicon via extending from a first backside pattern of the backside wiring layer toward the front-side wiring layer, wherein the first backside pattern is configured to apply a first supply voltage or a second supply voltage provided to at least one of the devices.

According to another aspect of the inventive concept, there is provided an integrated circuit including a plurality of blocks, wherein each of the plurality of blocks includes devices formed in an device layer between a front-side wiring layer and a backside wiring layer, and a block guard-ring surrounding the devices, wherein the block guard-ring includes a plurality of first through silicon vias arranged in the first horizontal direction in a first portion of the block guard-ring and passing through the device layer, the first portion extending in the first horizontal direction, and a plurality of second through silicon vias arranged in the second horizontal direction in a second portion of the block guard-ring and passing through the device layer, the second portion extending in a second horizontal direction intersecting with the first horizontal direction.

According to another aspect of the inventive concept, there is provided a method of manufacturing an integrated circuit, the method including disposing a plurality of blocks based on input data, generating a plurality of block guard-rings respectively surrounding the plurality of blocks, generating backside patterns in the backside wiring layer, and generating output data defining the plurality of blocks, the plurality of block guard-rings, and the backside patterns, wherein the generating of the plurality of block guard-rings includes defining a guard-ring region, and disposing a plurality of through silicon vias passing through an device layer between a front-side wiring layer and the backside wiring layer in the guard-ring region, wherein the generating of the backside patterns in the backside wiring layer includes generating patterns respectively connected to the plurality of through silicon vias.

### BRIEF DESCRIPTION OF THE DRAWINGS

Embodiments will be more clearly understood from the following detailed description taken in conjunction with the accompanying drawings in which:

FIG. 1 is a diagram illustrating a layout of an integrated circuit according to an example embodiment;

FIGS. 2A to 2C are diagrams illustrating layouts of an integrated circuit according to example embodiments;

FIGS. 3A to 3D are diagrams illustrating examples of active devices according to example embodiments;

FIG. 4 is a diagram illustrating a guard-ring according to an example embodiment;

FIGS. 5A and 5B are cross-sectional views illustrating cross-sections of a layout of an integrated circuit according to example embodiments;

FIGS. 6A and 6B are diagrams illustrating examples of blocks according to example embodiments;

FIG. 7 is a flowchart illustrating a method of fabricating an integrated circuit according to an example embodiment;

FIG. 8 is a flowchart illustrating a method of fabricating an integrated circuit according to an example embodiment;

FIG. 9 is a block diagram illustrating a system-on-chip according to an example embodiment; and

FIG. 10 is a block diagram illustrating a computing system including a memory storing a program according to an example embodiment.

### DETAILED DESCRIPTION OF THE EMBODIMENTS

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. The same reference numerals or the same reference designators may denote the same components or elements throughout the specification and drawings.

As used herein, components described as being “electrically connected” are configured such that an electrical signal can be transferred from one component to the other. Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

The same reference numerals or the same reference designators may denote the same components or elements throughout the specification and drawings.

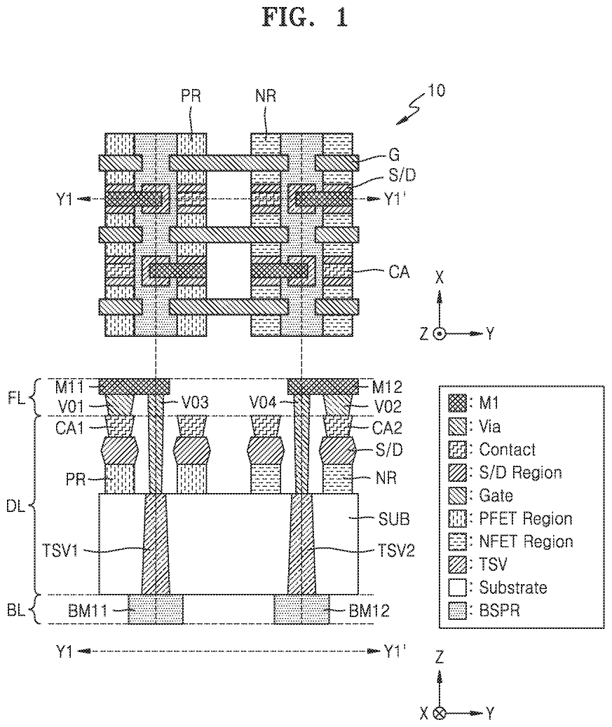

FIG. 1 is a diagram illustrating a layout of an integrated circuit 10 according to an example embodiment. FIG. 1 shows both a plan view of the integrated circuit 10 and a cross-sectional view of the integrated circuit 10 along the line Y1-Y1′.

Herein, the X-axis direction and the Y-axis direction may be referred to as a first direction (or first horizontal direction) and a second direction (or second horizontal direction), respectively, and the Z-axis direction may be referred to as a vertical third direction. A plane consisting of the X- and Y-axes may be referred to as a horizontal plane, and a component disposed in the +Z direction relative to other components may be referred to as being above the other components, and a component disposed in the −Z direction relative to other components may be referred to as being under the other component. In addition, the area of the component may refer to the size occupied by the component on a plane parallel to the horizontal plane, and the width of the component may refer to a length in a direction orthogonal to a direction in which the component extends. A surface exposed in the +Z direction may be referred to as a top surface, a surface exposed in the −Z direction may be referred to as a bottom surface, and a surface exposed in the ±X direction or ±Y direction may be referred to as a side surface. A pattern made of a conductive material, such as a pattern of a wiring layer, may be referred to as a conductive pattern or may simply be referred to as a pattern. Also, a pattern extending in one direction may be referred to as a line.

In the drawings herein, only some layers may be shown for convenience of illustration, and vias connecting an upper pattern and a lower pattern may be shown for understanding despite being located under the upper pattern. Also, for convenience of illustration, the gate electrodes are illustrated as continuously extending in the Y-axis direction, but it is noted that each of the gate electrodes may be divided into two or more gate electrodes by, for example, a gate cut.

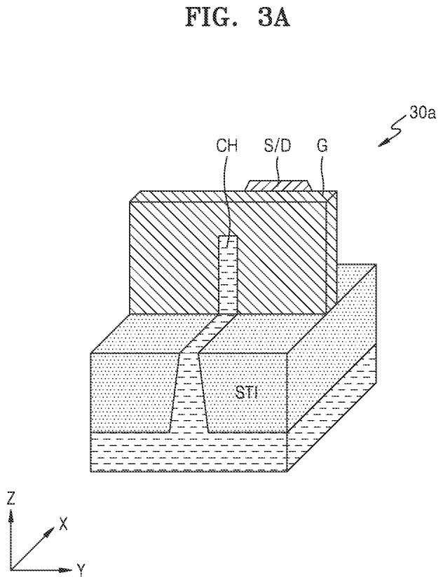

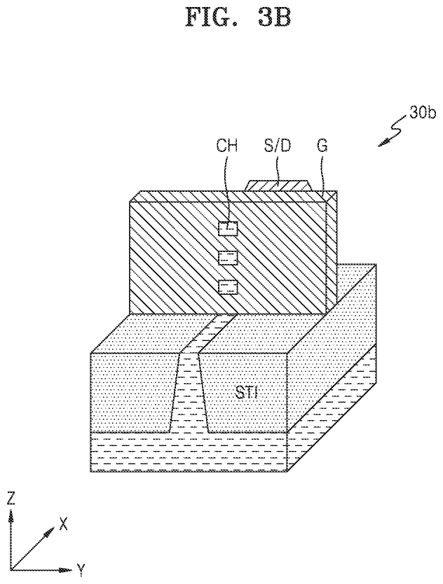

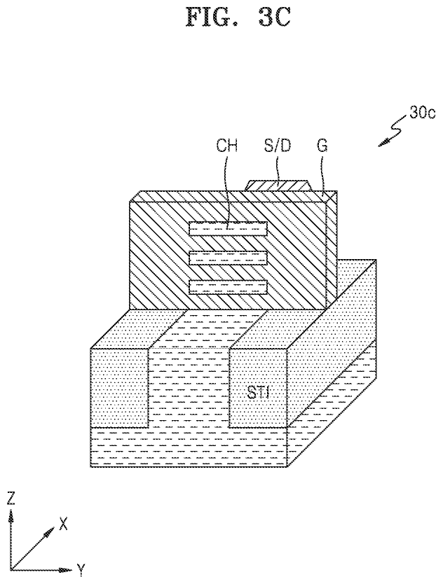

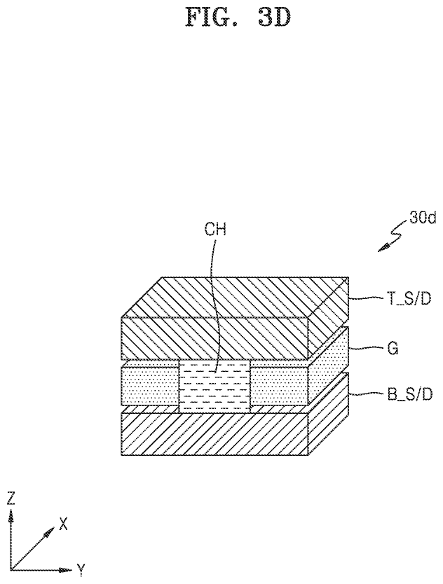

Referring to the plan view of FIG. 1, the integrated circuit 10 may include p-channel field effect transistor (PFET) regions PR and n-channel field effect transistor (NFET) regions NR extending lengthwise in the X-axis direction and may include gate electrodes G extending lengthwise in the Y-axis direction. Source/drain regions S/D may be formed on both sides of the gate electrode G, and contacts CA (including, for example, contacts CA1 and CA2) may be formed on the source/drain regions S/D. A channel may be formed between the source/drain regions S/D under the gate electrode G, and examples of the channel are described below with reference to FIGS. 3A to 3D.

Referring to the cross-sectional view of FIG. 1, the integrated circuit 10 may include a device layer DL, a front-side wiring layer FL, and a backside wiring layer BL, and the device layer DL may be between the front-side wiring layer FL and the backside wiring layer BL. The device layer DL may include devices. For example, as shown in FIG. 1, a transistor may be formed by a gate electrode G and a source/drain region S/D in the device layer DL. In some embodiments, the device layer DL may include not only active devices such as transistors but also passive devices such as resistors and capacitors. Examples of a transistor as an active device are described below with reference to FIGS. 3A to 3D.

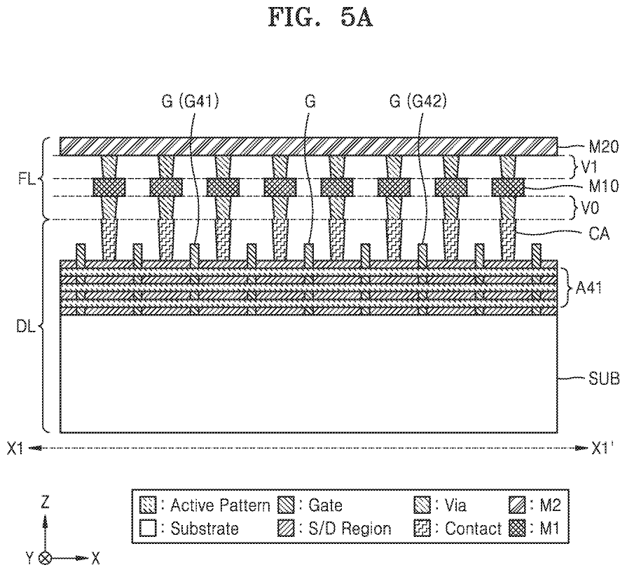

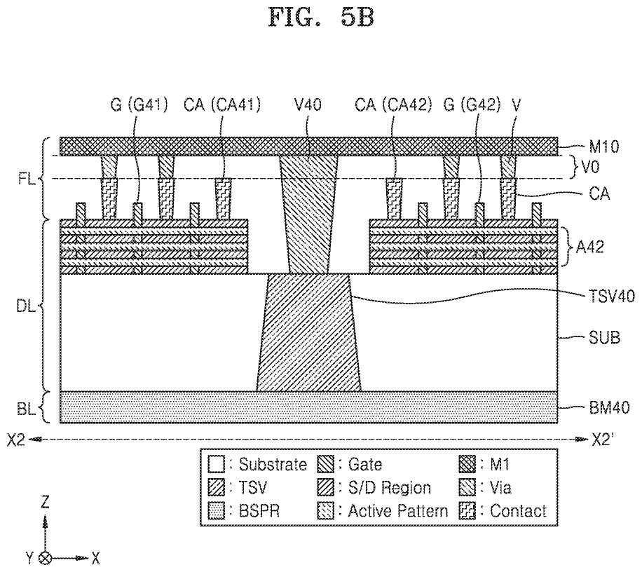

The front-side wiring layer FL may include patterns for power and signal routing. The front-side wiring layer FL may further include vias V including, for example, first and second vias V01 and V02. For example, as shown in FIG. 1, the front-side wiring layer FL may include a first via V01 connected to the first contact CA1, a second via V02 connected to the second contact CA2, and a first front-side pattern M11 and a second front-side pattern M12 of a first conductive layer M1. For example, the first via V01 may contact a top surface of the first contact CA1, the second via V02 may contact a top surface of the second contact CA2, the first front-side pattern M11 may contact a top surface of the first via V01, and the second front-side pattern M12 may contact a top surface of the second via V02. The front-side wiring layer FL may further include upper wiring layers (e.g., second conductive layer M2 of FIG. 5A) on the first conductive layer M1 and via layers between the first conductive layer M1 and the upper wiring layers and between the upper wiring layers. The backside wiring layer BL may include interconnections for power and/or signal routing. For example, as shown in FIG. 1, the backside wiring layer BL may include a first backside pattern BM11 and a second backside pattern BM12 extending lengthwise in the X-axis direction. The backside wiring layer BL may further include lower wiring layers and via layers between the backside patterns and the lower wiring layers and between the lower wiring layers.

The integrated circuit 10 may include through silicon vias TSV (e.g., through silicon vias TSV1 and TSV2) passing through the substrate SUB in the device layer DL. For example, as shown in FIG. 1, the integrated circuit 10 may include a first through silicon via TSV1 and a second through silicon via TSV2 extending in the Z-axis direction. The first through silicon via TSV1 may be connected to the top surface of the first backside pattern BM11 of the backside wiring layer BL and may extend from the first backside pattern BM11 toward the first front-side pattern M11 of the front-side wiring layer FL. For example, the first through silicon via TSV1 may contact the top surface of the first backside pattern BM11. The second through silicon via TSV2 may be connected to the top surface of the second backside pattern BM12 of the backside wiring layer BL and may extend from the second backside pattern BM12 toward the second front-side pattern M12 of the front-side wiring layer FL. For example, the second through silicon via TSV2 may contact the top surface of the second backside pattern BM12. The third via V03 may extend in the Z-axis direction and connect the first front-side pattern M11 to the first through silicon via TSV1. For example, the third via V03 may contact a top surface of the first through silicon via TSV1 and a bottom surface the first front-side pattern M11. The fourth via V04 may extend in the Z-axis direction and connect the second front-side pattern M12 to the second through silicon via TSV2. For example, the fourth via V04 may contact a top surface of the second through silicon via TSV2 and a bottom surface the second front-side pattern M12.

The first backside pattern BM11 and the second backside pattern BM12 may be used to provide a positive or negative supply voltage to the device. For example, as shown in FIG. 1, the first backside pattern BM11 may provide a positive supply voltage to PFETs formed in PFET regions PR. Accordingly, a positive supply voltage may be provided to the PFETs from the first backside pattern BM11 through the first through silicon via TSV1, the third via V03, the first front-side pattern M11, the first via V01, and the first contact CA1. Also, the second backside pattern BM12 may provide a negative supply voltage to the NFETs formed in the NFET regions NR. Accordingly, a negative supply voltage may be provided to the NFETs from the second backside pattern BM12 through the second through silicon via TSV2, the fourth via V04, the second front-side pattern M12, the second via V02, and the second contact CA2. Like the first backside pattern BM11 and the second backside pattern BM12, a pattern formed in the backside wiring layer BL to supply power to devices may be referred to as a backside power rail (BSPR). For example, the first and second backside patterns BM11 and BM12 may be referred to as backside power rails (BSPR).

Appropriate arrangement of through silicon vias TSV may be required to stably provide supply voltage from the BSPR to devices, but due to the process of forming the through silicon via TSV and/or the effect on the peripheral structures of the through silicon via TSV, placement of through silicon vias TSV may be limited. As described below with reference to the drawings, the through silicon via TSV may be placed in a guard-ring surrounding the block, and accordingly, through-silicon vias TSV may be arranged without increasing the area of the integrated circuit 10, and at the same time, supply voltage may be stably provided to the devices.

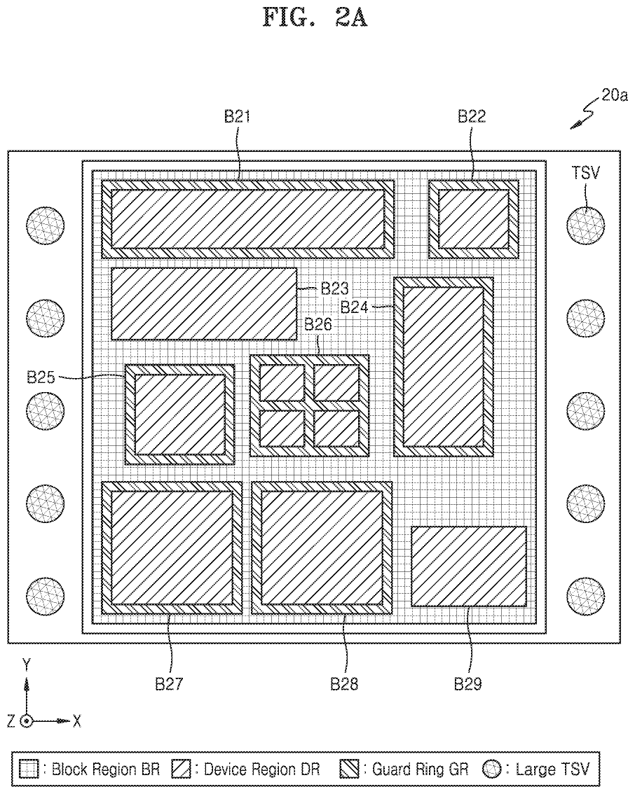

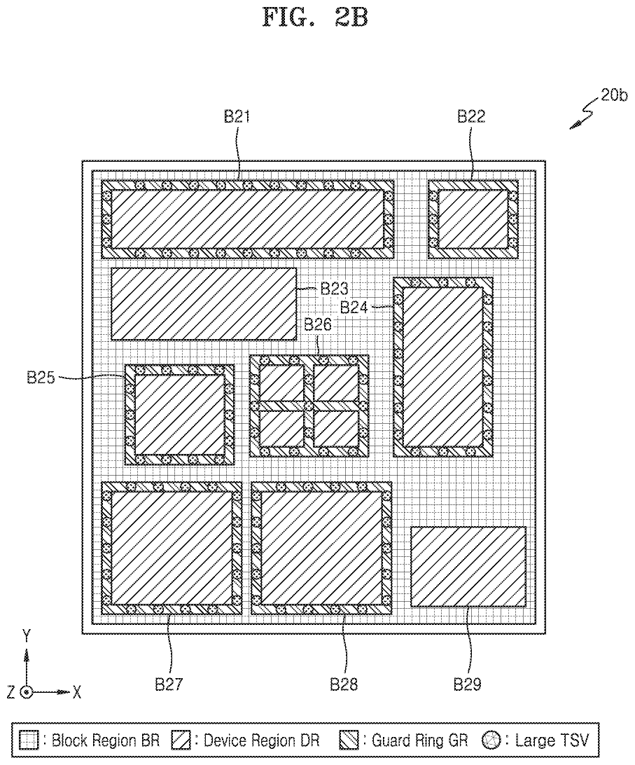

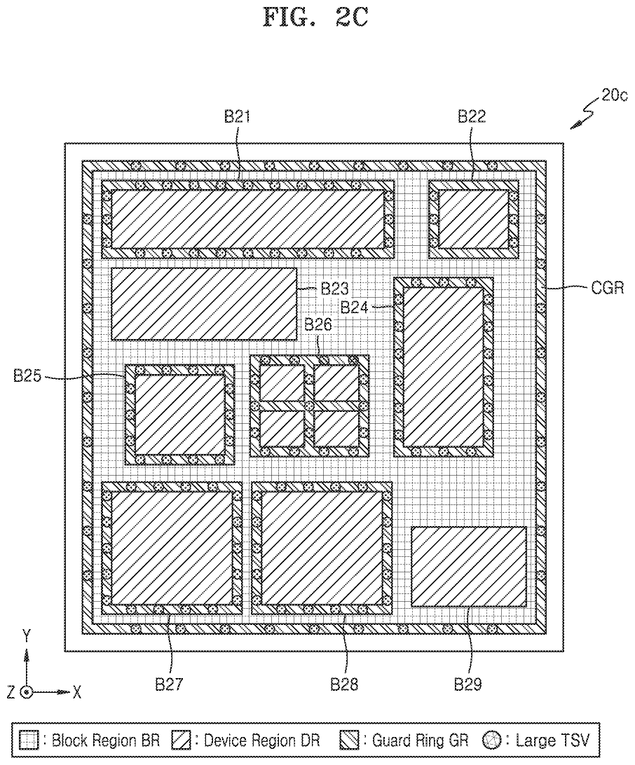

FIGS. 2A to 2C are diagrams illustrating layouts of an integrated circuit according to example embodiments. For example, FIGS. 2A to 2C each show layouts of an integrated circuit including a guard-ring. Hereinafter, duplicate descriptions of FIGS. 2A to 2C are not repeated.

Referring to FIG. 2A, an integrated circuit 20a may include first to ninth blocks B21 to B29 in a block region BR. Each of the first to ninth blocks B21 to B29 may include device regions DR in which devices are formed. Each of the first to ninth blocks B21 to B29 may be independently designed to perform unique functions. For example, the first block B21 may include devices constituting a circuit for processing an analog signal, such as an amplifier. The second block B22 may include at least one resistor. The third block B23 and the ninth block B29 may include devices constituting circuits that process digital signals, such as memory and logic circuits. The fourth block B24 may include devices constituting a circuit for processing mixed signals, such as an analog-to-digital converter (ADC) and a temperature sensor. The fifth block B25 may include at least one diode. The sixth block B26 may include at least one capacitor. The seventh block B27 and the eighth block B28 may include devices for electrostatic discharge (ESD) such as diodes.

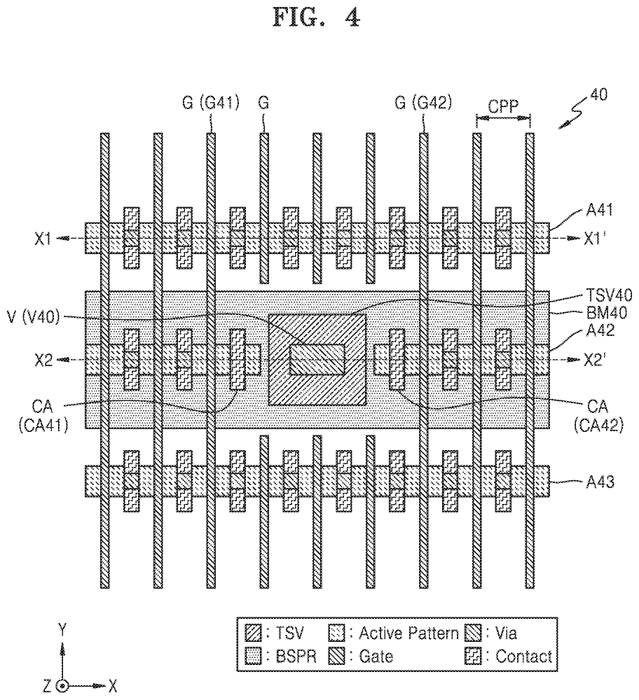

A block may include a guard-ring GR surrounding a device region DR in which devices are formed. For example, as shown in FIG. 2A, each of the first block B21, the second block B22, the fourth block B24, and the fifth to eighth blocks B25 to B28 may include a guard-ring GR surrounding the device region DR. The guard-ring GR may be provided to reduce an influence between blocks formed by different sub-processes in a semiconductor process and/or to reduce interference with neighboring blocks during operation. For example, the first block B21 including devices that process analog signals may include a guard-ring GR to block noise introduced from the surroundings. The second block B22 including at least one resistor may include a guard-ring GR to ensure desired characteristics of the resistor and reduce process variation. The fourth block B24 including devices for processing mixed signals may include a guard-ring GR to block noise introduced from the surroundings and to prevent noise generated inside from propagating to the surroundings. A diode included in the fifth block B25 may be used to remove plasma charges generated in a semiconductor process, and the fifth block B25 may include a guard-ring GR additionally providing a discharge path. The sixth block B26 including at least one capacitor may include a guard-ring GR to secure desired characteristics of the capacitor and reduce process variation, and as shown in FIG. 2A, may include a guard-ring GR crossing the device region DR. The seventh block B27 and the eighth block B28 including devices for ESD may include a guard-ring GR to secure designed characteristics of the devices and provide an ESD discharge path. In some embodiments, a block may include a device region DR without a guard ring, such as the third block B23 and the ninth block B29 of FIG. 2A. In some other embodiments, differently from that shown in FIG. 2A, the third block B23 and the ninth block B29 including devices that process digital signals may also include a guard-ring. Herein, a guard-ring GR surrounding a device region DR of a block, such as the guard-rings GR of FIG. 2A, may be referred to as a block guard-ring GR, and as described below with reference to FIG. 2C, a guard-ring surrounding a plurality of blocks, that is, a block region BR, may be referred to as a chip guard-ring CGR. An example of the guard-ring GR is described below with reference to FIG. 4.

Through silicon vias TSV may be placed to receive the supply voltage from the backside pattern of the backside wiring layer. For example, as shown in FIG. 2A, through silicon vias TSV may be placed outside the block region BR of the integrated circuit 20a. As discussed above with reference to FIG. 1, constraints may exist on the placement of through silicon vias TSV, and when placed adjacent to the edges of integrated circuit 20a as shown in FIG. 2A, through silicon vias TSV may easily meet the constraints. The through silicon via TSV of FIG. 2A may have a larger size (e.g., larger area in plan view) than the through silicon via TSV described below with reference to FIGS. 2B and 2C. Herein, the through silicon vias TSV of FIG. 2A may be referred to as large through silicon vias TSV, and the through silicon vias TSV of FIGS. 2B and 2C may be referred to as small through silicon vias TSV.

Referring to FIG. 2B, an integrated circuit 20b may include first to ninth blocks B21 to B29 in a block region BR. As described above with reference to FIG. 2A, the first to ninth blocks B21 to B29 may be designed independently of each other to perform unique functions, respectively. Also, the first block B21, the second block B22, the fourth block B24, and the fifth to eighth blocks B25 to B28 may include guard-rings GR, respectively.

Through silicon vias TSV may be placed in the guard-rings GR and may be connected to the patterns of the backside wiring layer (e.g., first and second backside patterns BM11 and BM12 of the backside wiring layer BL of FIG. 1). For example, as shown in FIG. 2B, through silicon vias TSV may be placed in the guard-rings GR of the first block B21, the second block B22, the fourth block B24, and the fifth to eighth blocks B25 to B28. In some embodiments, like the through silicon vias TSV disposed in the guard-rings GR of the first block B21, the fourth block B24, the fifth block B25, the seventh block B27, and the eighth block B28, the through silicon vias TSV may be disposed in portions extending in the X-axis direction and in the Y-axis direction of the guard-rings GR. In some embodiments, like the through silicon vias TSV disposed in the guard-ring GR of the second block B22, the through silicon vias TSV may be disposed in a portion extending in only one direction of the guard-ring GR, for example, in the Y-axis direction. In some embodiments, like the through silicon vias TSV disposed in the guard-ring GR of the sixth block B26, through silicon vias TSV may be placed in a portion of the guard-ring GR that crosses the device region DR of the block. The arrangement and number of through silicon vias TSV are not limited to those shown in FIG. 2B. Herein, a through silicon via TSV disposed in a guard-ring GR may be referred to as a through silicon via TSV included in a guard-ring GR.

As described above with reference to FIG. 1, each of the blocks (e.g., first block B21, the second block B22, the fourth to eighth blocks B24 to B28) may include a front-side pattern of a front-side wiring layer (e.g., first and second front-side patterns M11 and M12 of the front-side wiring layer FL of FIG. 1) electrically connected to a through silicon via TSV disposed in a guard-ring GR, and the front-side pattern may be connected to devices of the device region DR to provide a supply voltage. Compared to the integrated circuit 20a of FIG. 2A, the integrated circuit 20b of FIG. 2B may have a reduced area. Also, in the integrated circuit 20b of FIG. 2B, through silicon vias TSV may be closer to the devices and the devices may receive a supply voltage through a shortened path. Accordingly, IR-drop may be reduced and the performance and reliability of the integrated circuit 20b may be increased. As shown in FIG. 2B, in the integrated circuit 20b, through silicon vias TSV may be distributed throughout the integrated circuit 20b, and due to the uniform density of the through silicon vias TSV, the difficulty of the semiconductor process may be reduced. The through silicon vias TSV disposed in the guard-ring GR may function as a wall biased with a constant potential, and accordingly, an effect of blocking noise propagation between blocks may be increased.

Referring to FIG. 2C, an integrated circuit 20c may include first to ninth blocks B21 to B29 in a block region BR. As described above with reference to FIG. 2A, the first to ninth blocks B21 to B29 may be designed independently of each other to perform unique functions, respectively. In addition, each of the first block B21, the second block B22, the fourth block B24, and the fifth to eighth blocks B25 to B28 may include a guard-ring GR, and through silicon vias TSV may be placed in the guard-rings GR.

The integrated circuit 20c may include a guard-ring CGR surrounding a block region BR. As shown in FIG. 2C, a guard-ring CGR may surround the first to ninth blocks B21 to B29 and may be referred to as a chip guard-ring CGR. Similar to the block guard-ring GR described above with reference to FIG. 2B, through silicon vias TSV may be disposed in a chip guard-ring CGR surrounding a block region BR. Through silicon vias TSV disposed in the chip guard-ring CGR may be connected to backside patterns of the backside wiring layer (e.g., first and second backside patterns BM11 and BM12 of the backside wiring layer BL of FIG. 1) and may be electrically connected to patterns of the front-side wiring layer (e.g., first and second front-side patterns M11 and M12 of the front-side wiring layer FL of FIG. 1). When a supply voltage is applied to the backside patterns, through silicon vias TSV disposed in the guard-ring CGR may be included in a path for supplying the supply voltage to the blocks.

FIGS. 3A to 3D are diagrams illustrating examples of active devices according to example embodiments. For example, FIG. 3A shows a FinFET 30a, FIG. 3B shows a GAAFET 30b, FIG. 3C shows a MBCFET 30c, and FIG. 3D shows a VFET 30d. For convenience of illustration, FIGS. 3A to 3C show a state in which one of the two source/drain regions is removed, and FIG. 3D shows a cross-section of the VFET 30d with a plane parallel to the plane formed by the Y and Z axes and passing through the channel CH of VFET 30d.

Referring to FIG. 3A, the FinFET 30a may be formed by a fin-shaped active pattern extending lengthwise in the X-axis direction between shallow trench isolation (STI) regions and a gate electrode G extending lengthwise in the Y-axis direction. The fin-shaped active pattern may form a channel CH, and the gate electrode G may surround side surfaces of the channel CH. Source/drain regions S/D may be formed on both sides of the gate electrode G in the X-axis direction, and thus, the source and drain may be spaced apart from each other in the X-axis direction. Although not illustrated, an insulating film may be formed between the channel CH and the gate electrode G. In some embodiments, the FinFET 30a may be formed by a plurality of active patterns spaced apart from each other in the Y-axis direction and the gate electrode G.

Referring to FIG. 3B, the GAAFET 30b may be formed by active patterns, that is, nanowires, spaced apart from each other in the Z-axis direction and extending lengthwise in the X-axis direction, and the gate electrode G extending lengthwise in the Y-axis direction. The active patterns may form channels CH, and the gate electrode G may surround side surfaces of the channels CH. Source/drain regions S/D may be formed on both sides of the gate electrode G in the X-axis direction, and thus, the source and drain may be spaced apart from each other in the X-axis direction. Although not illustrated, an insulating film may be formed between the channel CH and the gate electrode G. The number of nanowires included in the GAAFET 30b is not limited to the number shown in FIG. 3B.

Referring to FIG. 3C, the MBCFET 30c may be formed by active patterns, that is, nanosheets, spaced apart from each other in the Z-axis direction and extending lengthwise in the X-axis direction, and the gate electrode G extending lengthwise in the Y-axis direction. The active patterns may form channels CH, and the gate electrode G may surround side surfaces of the channels CH. Source/drain regions S/D may be formed on both sides of the gate electrode G in the X-axis direction, and thus, the source and drain may be spaced apart from each other in the X-axis direction. Although not illustrated, an insulating film may be formed between the channel CH and the gate electrode G. The number of nanosheets included in the MBCFET 30c is not limited to the number shown in FIG. 3C.

Referring to FIG. 3D, the VFET 30d has a top source/drain T_S/D and a bottom source/drain B_S/D spaced apart from each other in the Z-axis direction with the channel CH therebetween. The VFET 30d may include a gate electrode G surrounding the circumference of the channel CH between the top source/drain T_S/D and the bottom source/drain B_S/D. Although not illustrated, an insulating film may be formed between the channel CH and the gate electrode G.

Hereinafter, an integrated circuit including the FinFET 30a or the MBCFET 30c is mainly described, but the devices included in the integrated circuit are not limited to the examples of FIGS. 3A to 3D. For example, an integrated circuit may include a ForkFET having a structure in which an N-type transistor and a P-type transistor are more closely disposed as the nanosheets for the P-type transistor and the nanosheets for the N-type transistor are separated by a dielectric wall. Also, the integrated circuit may include bipolar junction transistors as well as FETs, such as complementary FETs (CFETs), negative CFETs (NCFETs), carbon nanotube (CNT) FETs, and the like.

FIG. 4 is a diagram illustrating a guard-ring 40 according to an example embodiment. As described above with reference to the drawings, an integrated circuit may include a block guard-ring GR surrounding a block and/or a chip guard-ring CGR surrounding a block region BR, and the through silicon vias TSV may be placed in the block guard-ring GR and/or the chip guard-ring CGR. The guard-ring 40 may correspond to a portion of a block guard-ring GR including one through silicon via TSV or a portion of a chip guard-ring CGR including one through silicon via TSV, such as the block guard-ring GR and chip guard-ring CGR illustrated in FIGS. 2A-2C.

Referring to FIG. 4, the guard-ring 40 may include first to third active patterns A41 to A43 extending lengthwise in parallel to each other in the X-axis direction and gate electrodes G (including, for example, first and second gate electrodes G41 and G42) extending lengthwise in parallel to each other in the Y-axis direction. In some embodiments, each of the first to third active patterns A41 to A43 may correspond to a fin described above with reference to FIG. 3A, a nanowire described above with reference to FIG. 3B, or a nanosheet described above with reference to FIG. 3C. The number of active patterns and the number of gate electrodes G included in the guard-ring 40 are not limited to those shown in FIG. 4. As shown in FIG. 4, the pitch of the gate electrodes G may be referred to as contacted poly pitch (CPP).

The guard-ring 40 may include contacts CA (including, for example, first and second contacts CA41 and CA42) extending in the Y-axis direction between the gate electrodes and vias V (including, for example, vias V0, V1, and V40) connected to the contacts CA. Although not shown in FIG. 4 for convenience of illustration, as described below with reference to FIGS. 5A and 5B, the guard-ring 40 may include a front-side pattern (e.g., front-side pattern M10 of FIG. 5B) of the first conductive layer M1, and a contact CA may be electrically connected to the front-side pattern through a via V. Herein, a contact CA connected to a source/drain region S/D between gate electrodes G may be referred to as a source/drain contact.

In some embodiments, a contact connected to the gate electrode, that is, a gate contact may be omitted from the guard-ring 40. For example, as shown in FIG. 4, the guard-ring 40 may include only source/drain contacts CA extending in the Y-axis direction between gate electrodes G. Accordingly, in such embodiments, the gate electrodes G may be electrically floated, and the source/drain contacts CA may be electrically biased. On the other hand, as described below with reference to FIGS. 5A and 5B, the source/drain regions S/D may be electrically biased by source/drain contacts CA electrically connected to the front-side patterns through vias V.

In the backside wiring layer BL, the backside pattern BM40 may extend lengthwise in the X-axis direction, and the through silicon via TSV40 may extend in the Z-axis direction from the backside pattern BM40 through the substrate SUB. In example embodiments, a top surface of the through silicon via TSV40 may be coplanar with a top surface of the substrate SUB, and a bottom surface of the through silicon via TSV40 may be coplanar with a bottom surface of the substrate SUB. The bottom surface of the through silicon via TSV40 may contact an upper surface of the backside pattern BM40. The via V40 may extend in the Z-axis direction from the through silicon via TSV40, and may be connected to a front-side pattern (e.g., front-side pattern M10 of FIG. 5B) of the first conductive layer M1. The bottom surface of the via V40 may contact the top surface of the through silicon via TSV40. The via V40 may be disposed between the contacts CA in the X-axis direction and may be disposed between the contacts CA in the Y-axis direction.

A through silicon via TSV40 may be disposed below the region between the gate electrodes. For example, as shown in FIG. 4, a through silicon via TSV40 may be disposed under a region between the first gate electrode G41 and the second gate electrode G42, and the via V40 may be disposed between the first gate electrode G41 and the second gate electrode G42. In some embodiments, the through silicon via TSV40 may have a longer length in the X-axis direction than the CPP in the X-axis direction. For example, as shown in FIG. 4, the through silicon via TSV40 may have a length in the X-axis direction that is longer than 1 CPP and shorter than 2 CPPs. To this end, as shown in FIG. 4, the three gate electrodes may be partially removed, two contacts may be removed, and the second active pattern A42 may be partially removed by 2 CPPs.

In some embodiments, vias disposed on contacts adjacent to the through silicon via TSV40 may be omitted. For example, as shown in FIG. 4, the first contact CA41 and the second contact CA42 may be adjacent to the through silicon via TSV40 or the via V40, and vias may not be disposed on the first contact CA41 and the second contact CA42.

FIGS. 5A and 5B are cross-sectional views illustrating cross-sections of a layout of an integrated circuit according to embodiments. For example, the cross-sectional view of FIG. 5A shows an example of a cross-section of the guard-ring 40 along the line X1-X1′ of FIG. 4, and the cross-sectional view of FIG. 5B shows an example of a cross-section of the guard-ring 40 along the line X2-X2′ of FIG. 4. In the following, FIGS. 5A and 5B are described with reference to FIG. 4.

Referring to FIG. 5A, the first active pattern A41 may extend in the X-axis direction on the substrate SUB. The first active pattern A41 may cross the gate electrodes G extending in the Y-axis direction. Source/drain regions S/D may be formed between the gate electrodes G, and contacts CA may be disposed on the source/drain regions S/D. Vias V0 may be formed on the contacts CA and may be respectively connected to front-side patterns M10 of the first conductive layer M1 extending in the Y-axis direction. Vias V1 may be formed on the front-side patterns M10 of the first conductive layer M1 and may be commonly connected to the front-side pattern M20 of the second conductive layer M2 extending in the X-axis direction. Accordingly, the source/drain regions S/D may be electrically connected to each other, and when a constant potential, for example, a supply voltage is applied to the front-side pattern M20 of the second conductive layer M2, the source/drain regions S/D may be biased with the supply voltage.

Referring to FIG. 5B, the second active pattern A42 may extend lengthwise in the X-axis direction on the substrate SUB. The second active pattern A42 may cross the gate electrodes G, which extend lengthwise in the Y-axis direction. Source/drain regions S/D may be formed between the gate electrodes G, and contacts CA may be disposed on the source/drain regions S/D. Vias V0 may be formed on the contacts CA and may be commonly connected to a front-side pattern M10 of the first conductive layer M1 extending in the X-axis direction.

The backside pattern BM40 may extend lengthwise in the X-axis direction under the substrate SUB. The through silicon via TSV40 may extend in the Z-axis direction from the top surface of the backside pattern BM40 and pass through the substrate SUB. The via V40 may extend in the Z-axis direction from the top surface of the through silicon via TSV40 and be connected to the front-side pattern M10 of the first conductive layer M1. Accordingly, the source/drain regions S/D may be electrically connected to the backside pattern BM40 and may be biased with a supply voltage when the supply voltage is applied to the backside pattern BM40. Devices included in the block may receive a positive supply voltage or a negative supply voltage via the front-side pattern M10.

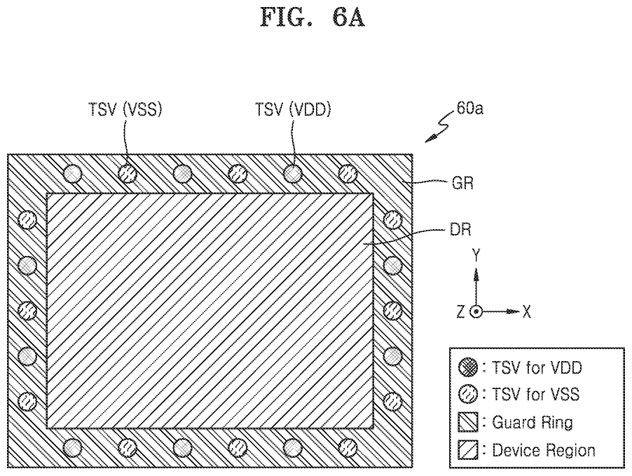

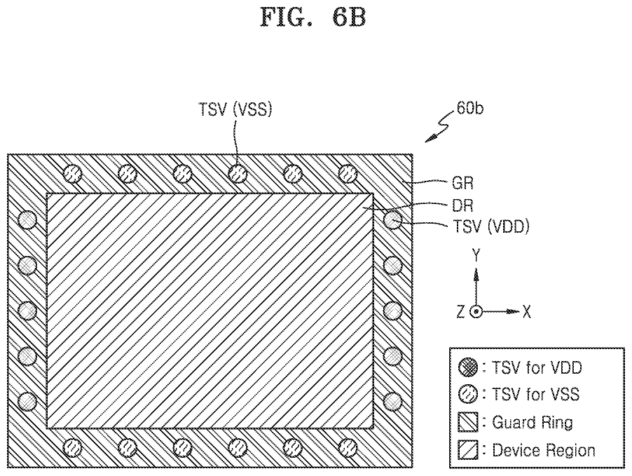

FIGS. 6A and 6B are diagrams illustrating examples of blocks according to example embodiments. Block 60a of FIG. 6A and block 60b of FIG. 6B may correspond to any of the first block B21, the second block B22, or the fourth to eighth blocks B24 to B28, as discussed herein. In some embodiments, a block may include through silicon vias TSV providing a positive supply voltage VDD to devices and through silicon vias providing a negative supply voltage VSS to devices. The arrangement of through silicon vias TSV providing positive supply voltage VDD and through silicon vias providing negative supply voltage VSS is not limited to that shown in FIGS. 6A and 6B.

Referring to FIG. 6A, a block 60a may include a device region DR and a guard-ring GR surrounding the device region DR. In the guard-ring GR, through silicon vias TSV providing a positive supply voltage VDD and through silicon vias TSV providing a negative supply voltage VSS may be alternately disposed. Referring to FIG. 6B, a block 60b may include a device region DR and a guard-ring GR surrounding the device region DR. Through silicon vias TSV providing a negative supply voltage VSS may be disposed at portions extending in the X-axis direction of the guard-ring GR, and through silicon vias TSV providing a positive supply voltage VDD may be disposed at portions extending in the Y-axis direction of the guard-ring GR. In some embodiments, a block may include through silicon vias TSV each providing three or more different supply voltages in the guard-ring GR.

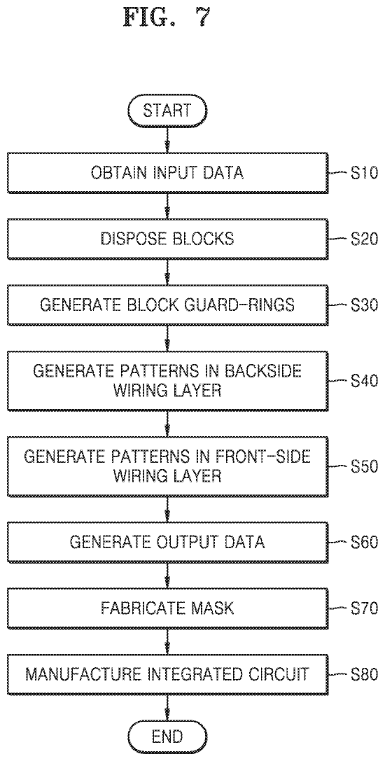

FIG. 7 is a flowchart showing a method of manufacturing an integrated circuit, according to an example embodiment. As shown in FIG. 7, the method of manufacturing an integrated circuit may include a plurality of operations S10 to S80. A series of operations S10 to S60 of generating output data from input data among the plurality of operations S10 to S80 may be collectively referred to as a method of designing a semiconductor. In some embodiments, a method of designing a semiconductor may be performed by a semiconductor design tool. Hereinafter, FIG. 7 is described with reference to FIG. 2B.

Referring to FIG. 7, in operation S10, input data may be obtained. Input data may define blocks to be included in an integrated circuit. For example, the input data may define device regions DR of the first to ninth blocks B21 to B29. In some embodiments, the input data may define the requirements of the blocks. For example, the input data may define the minimum distance between the first block B21 and other blocks.

In operation S20, blocks may be arranged. For example, the semiconductor design tool may arrange the first to ninth blocks B21 to B29 based on the input data obtained in operation S10. The semiconductor design tool may arrange the first to ninth blocks B21 to B29 so as not to overlap each other. If the input data defines the requirements of the blocks, the semiconductor design tool may refer to the input data to place the blocks such that the requirements are met. For example, the first to ninth blocks B21 to B29 may be spaced apart from each other by a distance defined from input data or more.

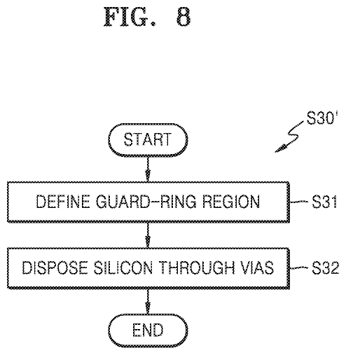

In operation S30, block guard-rings GR may be generated. As described above with reference to the figures, the block guard-ring GR surrounding the block may include through silicon vias TSV that provide a supply voltage to the devices while providing a variety of useful functions. When the first to ninth blocks B21 to B29 are arranged in operation S20, the semiconductor design tool may generate block guard-rings GR surrounding each of the first block B21, the second block B22, the fourth block B24, and the fifth to eighth blocks B25 to B28. In some embodiments, as described above with reference to FIG. 2C, a chip guard-ring CGR may be generated surrounding the placed blocks, that is, surrounding a block region BR, and the chip guard-ring CGR may include through silicon vias TSV. An example of operation S30 is described below with reference to FIG. 8.

In operation S40, patterns may be generated in the backside wiring layer (e.g., backside wiring layer BL of FIG. 5B). The block guard-ring GR disposed in operation S30 may include through silicon vias TSV, and the semiconductor design tool may generate patterns connected to through silicon vias TSV in the backside wiring layer BL, that is, backside patterns (e.g., backside pattern BM40 of FIG. 5B). A positive or negative supply voltage may be applied to the backside patterns, and thus, a positive or negative supply voltage may be applied to through silicon vias TSV.

In operation S50, patterns may be generated in the front-side wiring layer (e.g., front-side wiring layer FL of FIGS. 5A and 5B). The block guard-ring GR disposed in operation S30 may include through silicon vias TSV, and the semiconductor design tool may generate patterns electrically connected to through silicon vias TSV in the front-side wiring layer FL, that is, front-side patterns (e.g., front-side patterns M10 and M20 of FIG. 5A). In some embodiments, the semiconductor design tool may place vias (e.g., via V40 of FIG. 5B) on through silicon vias (e.g., TSV40 of FIG. 5B) and generate front-side patterns (e.g., front-side pattern M10 of FIG. 5B) connected to the vias.

In operation S60, output data may be generated. The output data may define blocks arranged in operation S20, block guard-rings GR generated in operation S30, backside patterns (e.g., backside pattern BM40 of FIG. 5B) generated in operation S40, and front-side patterns (e.g., front-side patterns M10 and M20 of FIG. 5A) generated in operation S50. The output data may include geometric information of the layout and may have a format such as GDSII. Output data may be referred to as layout data.

In operation S70, an operation of fabricating a mask may be performed. For example, optical proximity correction (OPC) for correcting a distortion phenomenon such as refraction caused by characteristics of light in photolithography may be applied to the output data. Patterns on the mask may be defined to form patterns disposed on a plurality of layers based on OPC-applied data, and at least one mask (or photomask) for forming patterns of each of a plurality of layers may be manufactured. In some embodiments, the layout of the integrated circuit may be limitedly modified in operation S70, and limited modification of the integrated circuit in operation S70 is post-processing for optimizing the structure of the integrated circuit IC and may be referred to as design polishing.

In operation S80, an operation of manufacturing an integrated circuit IC may be performed. For example, an integrated circuit may be manufactured by patterning a plurality of layers using at least one mask fabricated in operation S70. For example, the front-end-of-line (FEOL) process may include planarizing and cleaning a wafer, forming a trench, forming a well, forming a gate electrode, and forming sources and drains. With the FEOL, individual devices such as transistors, capacitors, resistors, and the like may be formed on a substrate. For example, the back-end-of-line (BEOL) process may include performing silicidation on a gate, a source and a drain, adding a dielectric, performing planarization, forming a hole, adding a metal layer, forming a via, and forming a passivation layer. With the BEOL, individual devices such as transistors, capacitors, and resistors may be interconnected. In some embodiments, the middle-of-line (MOL) process may be performed between the FEOL and the BEOL, and contacts may be formed on separate devices. Then, the integrated circuit may be packaged in a semiconductor package and used as a component in various applications.

FIG. 8 is a flowchart showing a method of manufacturing an integrated circuit, according to an example embodiment. For example, the flowchart of FIG. 8 shows an example of operation S30 of FIG. 7. As described above with reference to FIG. 7, block guard-rings GR may be generated in operation S30′ of FIG. 8. As shown in FIG. 8, operation S30′ may include operation S31 and operation S32. Hereinafter, FIG. 8 is described with reference to FIG. 7.

Referring to FIG. 8, a guard-ring region may be defined in operation S31. For example, a semiconductor design tool may define a region surrounding a block as a guard-ring region. In some embodiments, the semiconductor design tool may identify a block to define a guard-ring region based on input data and may define a guard-ring region surrounding the identified block. In some embodiments, the semiconductor design tool may define a guard-ring region surrounding the block region BR. In some embodiments, the semiconductor design tool may define a guard-ring region across the device region DR.

In operation S32, through silicon vias TSV may be disposed. For example, the semiconductor design tool may place through silicon vias TSV in the guard-ring region defined in operation S31. Accordingly, through silicon vias may be arranged without increasing the area of the integrated circuit.

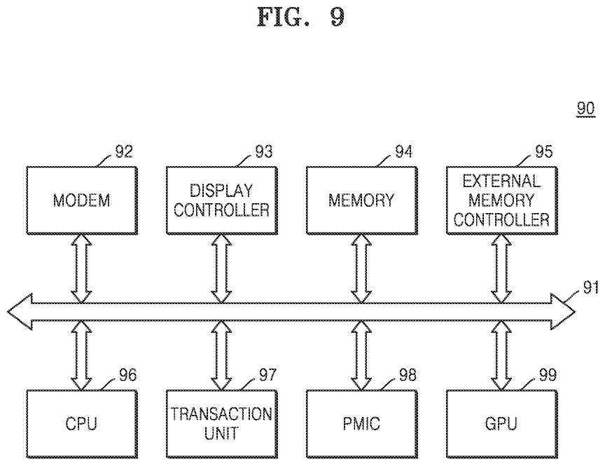

FIG. 9 is a block diagram illustrating a system on chip (SoC) 90 according to an example embodiment. The SoC 90 is a semiconductor device and may include an integrated circuit according to an example embodiment. The SoC 90 implements complex blocks such as intellectual property (IP) performing various functions on a single chip, and the SoC 90 may be designed by the method of designing an integrated circuit according to embodiments, and accordingly, the SoC 90 may have a reduced area despite including backside wiring layer patterns (e.g., backside pattern BM40 of FIG. 5B) and through silicon vias (e.g., through silicon vias TSV). Referring to FIG. 9, the SOC 90 may include a plurality of functional blocks, such as a modem 92, a display controller 93, a memory 94, an external memory controller 95, a central processing unit (CPU) 96, a transaction unit 97, a power management integrated circuit (PMIC) 98, and a graphics processing unit (GPU) 99, and each functional block of the SoC 90 may communicate with each other through a system bus 91.

The CPU 96, which may control the operation of the SoC 90 at the highest level, may control the operation of the other functional blocks (92 to 99). The modem 92 may demodulate a signal received from the outside of the SoC 90, or may modulate a signal generated inside the SoC 90 and transmit the modulated signal to the outside. The external memory controller 95 may control an operation of transmitting and receiving data from an external memory device connected to the SoC 90. For example, programs and/or data stored in the external memory device may be provided to the CPU 96 or the GPU 99 under the control of the external memory controller 95. The GPU 99 may execute program instructions related to graphic processing. The GPU 99 may receive graphic data through the external memory controller 95 and may transmit graphic data processed by the GPU 99 to the outside of the SoC 90 through the external memory controller 95. The transaction unit 97 may monitor data transactions of each functional block, and the PMIC 98 may control power supplied to each functional block according to the control of the transaction unit 97. The display controller 93 may transmit data generated inside the SoC 90 to the display by controlling the display (or display device) outside the SoC 90. The memory 94 may include non-volatile memory, such as Electrically Erasable Programmable Read-Only Memory (EEPROM) and flash memory, and may also include volatile memory, such as Dynamic Random Access Memory (DRAM) and Static Random Access Memory (SRAM).

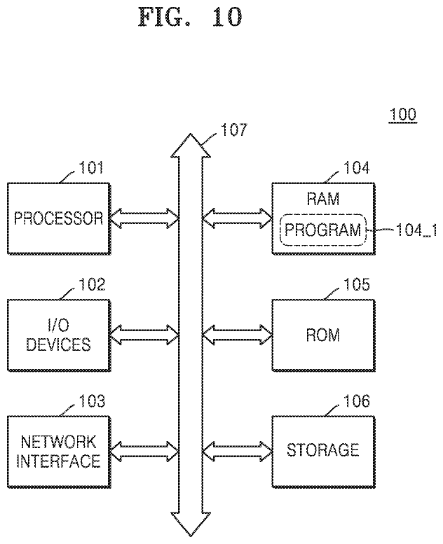

FIG. 10 is a block diagram illustrating a computing system 100 including a memory storing a program according to an example embodiment. A method of designing an integrated circuit, for example, at least some of the operations of the flowchart described above, according to example embodiments, may be performed on a computing system (or computer) 100.

The computing system 100 may be a fixed computing system, such as a desktop computer, a workstation, a server, and the like and may be a portable computing system, such as a laptop computer. As shown in FIG. 10, the computing system 100 may include a processor 101, input/output (I/O) devices 102, a network interface 103, random access memory (RAM) 104, read only memory (ROM) 105, and a storage device 106. The processor 101, the I/O devices 102, the network interface 103, the RAM 104, the ROM 105, and the storage device 106 may be connected to the bus 107 and may communicate with each other through the bus 107.

The processor 101 may be referred to as a processing unit, and for example, may include at least one core capable of executing an arbitrary instruction set (e.g., Intel Architecture-32 (IA-32), 64-bit extension IA-32, x86-64, PowerPC, Sparc, MIPS, ARM, IA-64, and the like), such as a micro-processor, an application processor (AP), a digital signal processor (DSP), and a GPU. For example, the processor 101 may access memory, that is, the RAM 104 or the ROM 105 through the bus 107, and may execute instructions stored in the RAM 104 or the ROM 105.

The RAM 104 may store a program 104_1 or at least a portion thereof for a method of designing an integrated circuit according to an embodiment, and the program 104_1 may cause the processor 101 to perform at least some of the operations included in a method of designing an integrated circuit, for example, the methods of FIG. 8. That is, the program 104_1 may include a plurality of instructions executable by the processor 101, and a plurality of instructions included in the program 104_1 may allow the processor 101 to perform at least some of the operations included in the above-described flowchart, for example.

The storage device 106 may not lose stored data even when the power supplied to the computing system 100 is cut off. For example, the storage device 106 may include a nonvolatile memory device or a storage medium such as magnetic tape, an optical disk, or a magnetic disk. Furthermore, the storage device 106 may be detachable from the computing system 100. The storage device 106 may store the program 104_1 according to an embodiment, and before the program 104_1 is executed by the processor 101, the program 104_1 or at least a portion thereof may be loaded from the storage device 106 into the RAM 104. Alternatively, the storage device 106 may store a file written in a program language, and the program 104_1 generated by a compiler or the like from a file or at least a part thereof may be loaded into the RAM 104.

The storage device 106 may store data to be processed by the processor 101 or data processed by the processor 101. That is, the processor 101 may generate data by processing data stored in the storage device 106 according to the program 104_1 and may store the generated data in the storage device 106. For example, the storage device 106 may store input data and/or output data of FIG. 7.

The I/O devices 102 may include an input device, such as a keyboard and a pointing device, and may include an output device, such as a display device and a printer. For example, a user may trigger execution of the program 104_1 by the processor 101 via the I/O devices 102, input the input data of FIG. 7, and check the output data of FIG. 7.

The network interface 103 may provide access to a network external to the computing system 100. For example, a network may include multiple computing systems and communication links, and the communication links may include wired links, optical links, wireless links, or any other type of links.

While the inventive concept has been particularly shown and described with reference to embodiments thereof, it will be understood that various changes in form and details may be made therein without departing from the spirit and scope of the following claims.

What is claimed is:

1. An integrated circuit comprising a plurality of blocks,
wherein each of the plurality of blocks comprises:
devices formed in a device layer between a front-side wiring layer and a backside wiring layer; and
a block guard-ring surrounding the devices,
wherein the block guard-ring comprises a first through silicon via extending from a first backside pattern of the backside wiring layer toward the front-side wiring layer, and
wherein the first backside pattern is configured to apply a first supply voltage or a second supply voltage provided to at least one of the devices.

2. The integrated circuit of claim 1,
wherein the block guard-ring further comprises a plurality of gate electrodes extending parallel to each other in a first horizontal direction and arranged in a second horizontal direction crossing the first horizontal direction, and
wherein the first through silicon via is disposed under a region between a first gate electrode and a second gate electrode among the plurality of gate electrodes.

3. The integrated circuit of claim 2,
wherein the plurality of gate electrodes comprise a third gate electrode adjacent to the first gate electrode, and
wherein a first pitch between the first gate electrode and the second gate electrode is greater than a second pitch between the first gate electrode and the third gate electrode.

4. The integrated circuit of claim 3, wherein the first through silicon via has a length longer than the second pitch in the second horizontal direction.

5. The integrated circuit of claim 2, wherein the plurality of gate electrodes are configured to be electrically floated.

6. The integrated circuit of claim 2,
wherein the block guard-ring further comprises a plurality of contacts extending in the first horizontal direction between the plurality of gate electrodes, and
wherein the plurality of contacts are configured to be electrically biased.

7. The integrated circuit of claim 6,
wherein the block guard-ring further comprises a plurality of vias each connected to one of the plurality of contacts and connected to a front-side pattern of the front-side wiring layer, and
wherein the plurality of contacts comprise a contact adjacent to the first through silicon via and not connected to the plurality of vias.

8. The integrated circuit of claim 6,
wherein the block guard-ring further comprises a via connected to the first through silicon via and a front-side pattern of the front-side wiring layer,
wherein the plurality of contacts comprise:
first contacts overlapping the via in the first horizontal direction; and
second contacts overlapping the via in the second horizontal direction, and wherein the via is disposed between the first contacts and between the second contacts.

9. The integrated circuit of claim 2, wherein the block guard-ring further comprises:
a plurality of through silicon vias aligned with the first through silicon via in the second horizontal direction; and
a front-side pattern extending in the second horizontal direction in the front-side wiring layer and electrically connected to the plurality of through silicon vias.

10. The integrated circuit of claim 9, wherein the first through silicon via is electrically connected to at least one of the devices via the front-side pattern.

11. The integrated circuit of claim 1,
wherein the block guard-ring further comprises a second through silicon via extending from a second backside pattern of the backside wiring layer toward the front-side wiring layer,
wherein the first backside pattern is configured to receive the first supply voltage, and
wherein the second backside pattern is configured to receive the second supply voltage.

12. The integrated circuit of claim 1, further comprising:
a chip guard-ring surrounding the plurality of blocks,
wherein the chip guard-ring comprises a through silicon via extending from a backside pattern of the backside wiring layer toward the front-side wiring layer.

13. An integrated circuit comprising a plurality of blocks,
wherein each of the plurality of blocks comprises:
devices formed in a device layer between a front-side wiring layer and a backside wiring layer; and
a block guard-ring surrounding the devices, and
wherein the block guard-ring comprises:
a plurality of first through silicon vias arranged in a first horizontal direction in a first portion of the block guard-ring and passing through the device layer, the first portion extending in the first horizontal direction; and
a plurality of second through silicon vias arranged in a second horizontal direction in a second portion of the block guard-ring and passing through the device layer, the second portion extending in a second horizontal direction intersecting with the first horizontal direction.

14. The integrated circuit of claim 13, wherein each of the plurality of first through silicon vias and the plurality of second through silicon vias is connected to a backside pattern of the backside wiring layer.

15. The integrated circuit of claim 14, wherein each of the plurality of first through silicon vias and the plurality of second through silicon vias is electrically connected to at least one of the devices via a front-side pattern of the front-side wiring layer.

16. The integrated circuit of claim 13, wherein each of the plurality of first through silicon vias and the plurality of second through silicon vias is configured to receive a first supply voltage or a second supply voltage provided to at least one of the devices.

17. The integrated circuit of claim 13, wherein the plurality of blocks comprise at least one of:
a block including active devices configured to process analog signals;
a block including at least one capacitor;
a block including at least one diode; and
a block including at least one resistor.

18. The integrated circuit of claim 13, further comprising:
a chip guard-ring surrounding the plurality of blocks,
wherein the chip guard-ring comprises a through silicon via extending from a backside pattern of the backside wiring layer toward a front-side wiring layer.

19. A method of manufacturing an integrated circuit, the method comprising:
disposing a plurality of blocks based on input data;
generating a plurality of block guard-rings respectively surrounding the plurality of blocks;
generating backside patterns in a backside wiring layer; and
generating output data defining the plurality of blocks, the plurality of block guard-rings, and the backside patterns,
wherein the generating of the plurality of block guard-rings comprises:
defining a guard-ring region; and
disposing a plurality of through silicon vias passing through a device layer between a front-side wiring layer and the backside wiring layer in the guard-ring region, and
wherein the generating of the backside patterns in the backside wiring layer comprises generating patterns respectively connected to the plurality of through silicon vias.

20. The method of claim 19, further comprising:
generating front-side patterns respectively connected to the plurality of through silicon vias in the front-side wiring layer.
